(19) United States
(12) Patent Application Publication
(10) Pub. No.: US 2025/0098229 A1
(43) Pub. Date: Mar. 20, 2025

(54) STRAIN INDUCING TRENCHES FOR SOURCE/DRAIN REGIONS

(71) Applicant: International Business Machines Corporation, Armonk, NY (US)

(72) Inventors: Sagarika Mukesh, Albany, NY (US); Ruilong Xie, Niskayuna, NY (US); Alexander Reznicek, Troy, NY (US); Tsung-Sheng Kang, Ballston Lake, NY (US)

(21) Appl. No.: 18/470,354

(22) Filed: Sep. 19, 2023

(51) Int. Cl. H01L 29/78; H01L 27/088; H01L 29/06; H01L 29/417; H01L 29/423; H01L 29/775; H01L 29/786

(52) U.S. Cl. CPC H10D 30/792; H10D 30/43; H10D 30/6735; H10D 30/6757; H10D 62/121; H10D 64/256; H10D 84/83

(57) ABSTRACT

A semiconductor device comprises at least one epitaxial source/drain region, and a dielectric layer disposed in a trench in the at least one epitaxial source/drain region. The dielectric layer comprises one of a material with a negative coefficient of thermal expansion and a material with a positive coefficient of thermal expansion.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming strain inducing trenches in source/drain regions.

In one embodiment, a semiconductor device comprises at least one epitaxial source/drain region, and a dielectric layer disposed in a trench in the at least one epitaxial source/drain region.

In another embodiment, a semiconductor device comprises a first nanosheet structure comprising a first plurality of gate structures alternately stacked with a first plurality of channel layers, and a second nanosheet structure comprising a second plurality of gate structures alternately stacked with a second plurality of channel layers. At least one epitaxial source/drain region is disposed between the first and second nanosheet structures. A dielectric layer is disposed in a trench in the at least one epitaxial source/drain region.

In another embodiment, a semiconductor device comprises a first epitaxial source/drain region corresponding to a first transistor and a second epitaxial source/drain region corresponding to a second transistor. A first dielectric layer is disposed in a first trench in the first epitaxial source/drain region, and a second dielectric layer is disposed in a second trench in the second epitaxial source/drain region. The first trench is disposed on a first side of the semiconductor device and the second trench is disposed on a second side of the semiconductor device opposite the first side.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure illustrating semiconductor nanosheet layers, according to an embodiment of the invention.

FIG. 2 depicts a cross-sectional view of a semiconductor structure following dummy gate formation, according to an embodiment of the invention.

FIG. 3 depicts a cross-sectional view of a semiconductor structure following gate spacer and bottom dielectric insulator layer (BDI) formation, according to an embodiment of the invention.

FIG. 4 depicts a cross-sectional view of a semiconductor structure following lateral recessing of sacrificial semiconductor layers, inner spacer formation and removal of exposed portions of the BDI layer, according to an embodiment of the invention.

FIG. 5 depicts a cross-sectional view of a semiconductor structure following growth of an etch stop layer and epitaxial source/drain region formation, according to an embodiment of the invention.

FIG. 6 depicts a cross-sectional view of a semiconductor structure following inter-layer dielectric (ILD) layer formation and planarization, dummy gate and sacrificial semiconductor layer removal, and replacement metal gate (RMG) formation, according to an embodiment of the invention.

FIG. 7 depicts a cross-sectional view of a semiconductor structure following middle-of-line (MOL) ILD deposition, according to an embodiment of the invention.

FIG. 8 depicts a cross-sectional view of a semiconductor structure following dielectric trench formation in an epitaxial source/drain region, according to an embodiment of the invention.

FIG. 9 depicts a cross-sectional view of a semiconductor structure following MOL contact formation, BEOL interconnect formation and carrier wafer bonding, according to an embodiment of the invention.

FIG. 10 depicts a cross-sectional view of a semiconductor structure following wafer flipping and semiconductor substrate removal, according to an embodiment of the invention.

FIG. 11 depicts a cross-sectional view of a semiconductor structure following etch stop layer removal and additional semiconductor substrate removal, according to an embodiment of the invention.

FIG. 12 depicts a cross-sectional view of a semiconductor structure following backside ILD layer formation and planarization, according to an embodiment of the invention.

FIG. 13 depicts a cross-sectional view of a semiconductor structure following backside ILD layer patterning for dielectric trenches and dielectric trench formation in epitaxial source/drain regions, according to an embodiment of the invention.

FIG. 14 depicts a cross-sectional view of a semiconductor structure following backside ILD layer patterning for backside contacts, backside contact formation and backside interconnect formation, according to an embodiment of the invention.

FIG. 15 depicts a cross-sectional view of a semiconductor structure including sacrificial placeholder layers following dielectric trench formation in an epitaxial source/drain region, MOL contact formation, BEOL interconnect formation and carrier wafer bonding, according to another embodiment of the invention.

FIG. 16 depicts a cross-sectional view of a semiconductor structure following wafer flipping and semiconductor substrate removal, according to another embodiment of the invention.

FIG. 17 depicts a cross-sectional view of a semiconductor structure following selective etch stop layer removal and additional semiconductor substrate removal, according to another embodiment of the invention.

FIG. 18 depicts a cross-sectional view of a semiconductor structure following backside ILD layer formation and planarization, according to another embodiment of the invention.

FIG. 19 depicts a cross-sectional view of a semiconductor structure following backside ILD layer opening for dielectric trenches, according to another embodiment of the invention.

FIG. 20 depicts a cross-sectional view of a semiconductor structure following removal of exposed sacrificial placeholders, according to another embodiment of the invention.

FIG. 21 depicts a cross-sectional view of a semiconductor structure following spacer formation and trench formation in epitaxial source/drain regions, according to another embodiment of the invention.

FIG. 22 depicts a cross-sectional view of a semiconductor structure following dielectric material deposition in trenches in epitaxial source/drain regions and in the backside ILD layer, according to another embodiment of the invention.

FIG. 23 depicts a cross-sectional view of a semiconductor structure following backside ILD layer patterning for a backside contact, according to another embodiment of the invention.

FIG. 24 depicts a cross-sectional view of a semiconductor structure following removal of an exposed sacrificial placeholder, backside contact formation and backside interconnect formation, according to an embodiment of the invention.

### DETAILED DESCRIPTION

Illustrative embodiments of the invention may be described herein in the context of illustrative methods for forming strain inducing trenches in source/drain regions, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

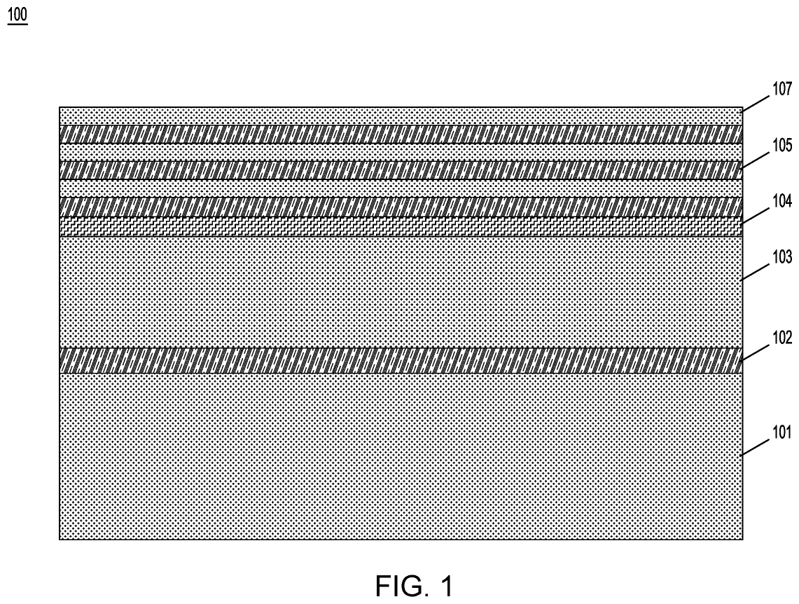

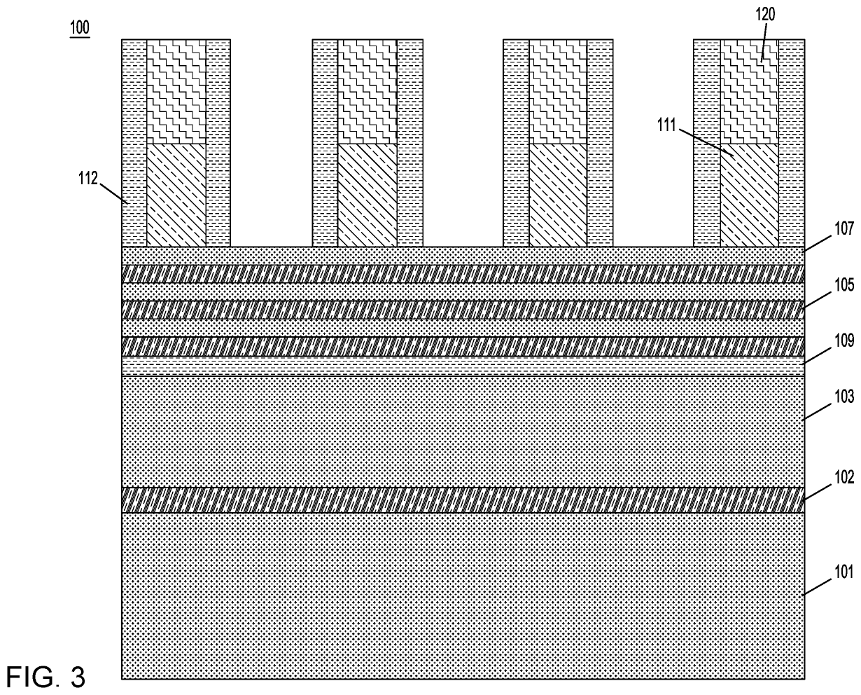

Referring to FIG. 1, a semiconductor structure 100 includes a stacked structure of sacrificial layers 105 and channel layers 107. In an illustrative embodiment, the sacrificial layers 105 comprise silicon germanium (SiGe) and the channel layers 107 comprise silicon. In illustrative embodiments, the sacrificial layers 105 comprise a germanium concentration of about 25% (e.g., SiGe25), but the embodiments are not necessarily limited to SiGe25 for the sacrificial layers 105. The lowermost sacrificial layer is formed on an additional sacrificial layer 104 including, for example, SiGe with a different concentration of germanium than that of the sacrificial layers 105. For example, the additional sacrificial layer 104 has, but is not necessarily limited to, a germanium concentration of about 55% (e.g., SiGe55). As explained in more detail herein, the additional sacrificial layer 104 has a different concentration of germanium than the sacrificial layers 105 so that the additional sacrificial layer 104 can be selectively etched and removed with respect to sacrificial layers 105 when forming a bottom dielectric isolation (BDI) layer (see, e.g., FIG. 3 including BDI layer 109).

First and second semiconductor substrates 101 and 103 comprise semiconductor material including, but not limited to, silicon (Si), III-V, II-V compound semiconductor materials or other like semiconductor materials. In addition, multiple layers of the semiconductor materials can be used as the semiconductor material of the first and second semiconductor substrates 101 and 103. An etch stop layer 102 is formed on the first semiconductor substrate 101, and may comprise, for example, silicon oxide (SiOₓ) (where x is for example, 2, 1.99 or 2.01), or SiGe. In illustrative embodiments, the etch stop layer 102 comprises a germanium concentration of about 25% (e.g., SiGe25), but the embodiments are not necessarily limited to SiGe25 for the etch stop layer 102. The second semiconductor substrate 103 comprising, for example, the same semiconductor material as the first semiconductor substrate 101, or other like semiconductor material, is formed on the etch stop layer 102.

The sacrificial layers 105 and channel layers 107 are epitaxially grown in an alternating and stacked configuration on the additional sacrificial layer 104. A first sacrificial layer 105 is followed by a first channel layer 107 on the first sacrificial layer 105, which is followed by a second sacrificial layer on the first channel layer 107, and so on. As can be understood, the sacrificial and channel layers 105 and 107 are epitaxially grown from their corresponding underlying semiconductor layers.

While three sacrificial layers 105 and three channel layers 107 are shown, the embodiments of the present invention are not necessarily limited to the shown number of sacrificial and channel layers 105 and 107, and there may be more or less layers in the same alternating configuration depending on design constraints. The sacrificial layers 105, as described further herein, are eventually removed and replaced by gate structures.

Although SiGe is described as a sacrificial material for sacrificial layers 105, other materials can be used as long as the sacrificial layers 105 have the property of being able to be removed selectively compared to the material of the channel layers 107.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height of the sacrificial layers 105 can be in the range of about 6 nm to about 15 nm depending on the application of the device. Also, in a non-limiting illustrative embodiment, a height of the channel layers 107 can be in the range of about 6 nm to about 15 nm depending on the desired process and application. In accordance with an embodiment of the present invention, each of the channel layers 107 has the same or substantially the same composition and size as each other, and each of the sacrificial layers 105 has the same or substantially the same composition and size as each other.

As used herein, “frontside or “first side” refers to a side on top of the first and/or second semiconductor substrates 101 and 103 and/or in front of, on top of or in an upward direction from the stacked nanosheet/gate and channel layers of the transistors in the orientation shown in the cross-sectional figures. As used herein, “backside” or “second side” refers to a side below the first and/or second semiconductor substrates 101 and 103 and/or behind, below or in a downward direction from the stacked nanosheet/gate and channel layers of the transistors in the orientation shown in the cross-sectional figures (e.g., opposite the “frontside”).

Although not shown, portions of the nanosheet stacks comprising the sacrificial layers 105 and channel layers 107 are removed, portions of the additional sacrificial layer 104 are removed and portions of the second semiconductor substrate 103 are recessed. Isolation regions (e.g., shallow trench isolation (STI) regions) are formed between the remaining nanosheet stacks, and remaining portions of the additional sacrificial layer 104 and the second semiconductor substrate 103. The dielectric material of the isolation regions may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

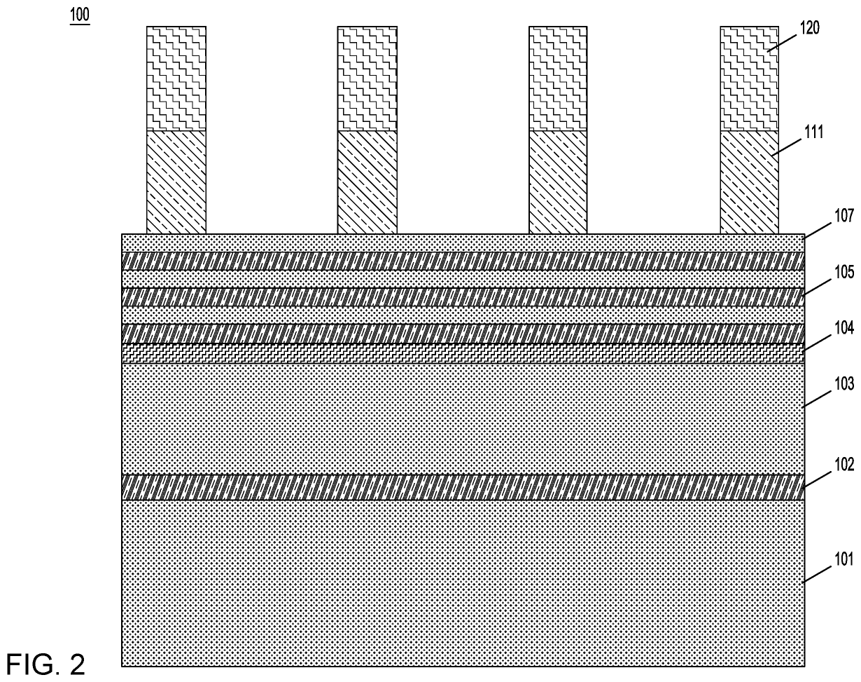

Referring to FIG. 2, dummy gate portions 111 are formed on the uppermost channel layer 107 and, although not shown, around the stacked nanosheet configuration of the sacrificial layers 105 and channel layers 107. The dummy gate portions 111 include, but are not necessarily limited to, an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer. Hardmask layers 120 are formed on the dummy gate portions 111. The hardmask layers 120 comprise, for example, a nitride such as SiN, SiON, SiCN, BN, SiBN, SiBCN, SiOCN, combinations thereof or other nitride material.

Referring to FIG. 3, the additional sacrificial layer 104 between the lowermost sacrificial layer 105 and second semiconductor substrate 103 is removed using, for example, an aqueous solution containing ammonium hydroxide (NH₄OH) and hydrogen peroxide (H₂O₂) or a gas containing hydrogen fluoride (HF) to selectively etch the additional sacrificial layer 104 with respect to the second semiconductor substrate 103, the sacrificial layers 105 and the channel layers 107. The selective etching removes the additional sacrificial layer 104 to form a vacant area where the BDI layer 109 is formed.

Dielectric material is deposited in place of the additional sacrificial layer 104 using deposition techniques such as, for example, CVD, PECVD, RFCVD, PVD, ALD, MBD, PLD, and/or LSMCD, followed by an etch back to form the BDI layer 109 on the second semiconductor substrate 103 in place of the additional sacrificial layer 104. The BDI layer 109 may comprise, for example, silicon oxide (SiOₓ) (where x is for example, 2, 1.99 or 2.01), silicon oxycarbide (SiOC), SIN, SION, SiCN, BN, SiBCN, SiOCN or some other dielectric. The BDI layer 109 is under a bottom surface of the lowermost sacrificial layer 105.

Gate spacers 112 are formed on sides of the hardmask layers 120 and dummy gate portions 111 by one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOₓ, and combinations thereof. According to an embodiment, the hardmask layers 120 and gate spacers 112 can be the same material or different materials. The gate spacers 112 can be formed by any suitable techniques such as deposition followed by directional etching. Deposition may include but is not limited to, ALD or CVD. Directional etching may include but is not limited to, reactive ion etching (RIE).

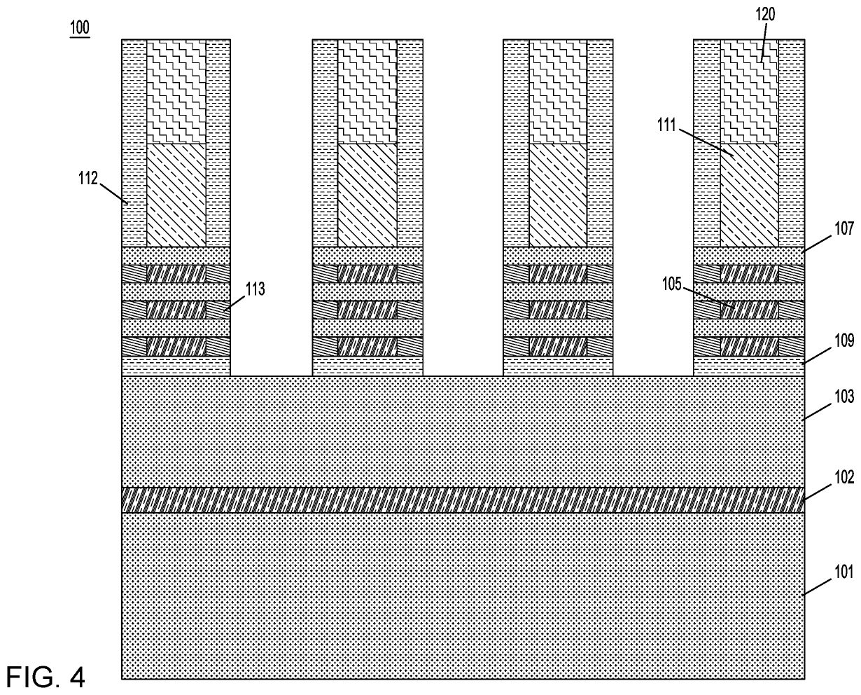

Referring to FIG. 4, exposed portions of the stacked sacrificial layers 105 and channel layers 107, which are not under the hardmask layers 120, gate spacers 112 and dummy gate portions 111, are removed using, for example, an etching process, such as RIE, where the hardmask layers 120, gate spacers 112 and dummy gate portions 111 are used as a mask. The portions of the stacked structures of sacrificial layers 105 and channel layers 107 under the hardmask layers 120, gate spacers 112 and under the dummy gate portions 111 remain after the etching process, and portions of the sacrificial layers 105 and channel layers 107 in areas that correspond to where source/drain regions will be formed are removed. In addition, following removal of the exposed portions of the stacked sacrificial layers 105 and channel layers 107, the exposed portions of the BDI layer 109 between the nanosheet and dummy gate stacks are removed to expose portions of the second semiconductor substrate 103. The process for removal of the exposed portions of the stacked sacrificial layers 105 and channel layers 107 includes, for example, CF₄ gas to selectively remove SiGe and a RIE process with H₂/CF₄ plasma to remove silicon. The process for removal of the exposed portions of the BDI layer 109 includes, for example, CF₄/H₂, CF₄/O₂/N₂, SF₆/O₂/N₂, SF₆/CH₄/N₂ and/or SF₆/CH₄/N₂/O₂.

Due to, for example, germanium in the sacrificial layers 105, lateral etching of the sacrificial layers 105 can be performed selective to the channel layers 107, such that the side portions of the sacrificial layers 105 can be removed to create vacant areas to be filled in by inner spacers 113. The material of the inner spacers 113 can comprise, but is not necessarily limited to, a nitride, such as, SiN, SiON, SiCN, BN, SiBN, SiBCN or SiOCN. Gate spacers 112 are positioned on the nanosheet stacks on opposite lateral sides of the dummy gate portions 111. In an illustrative embodiment, the gate spacers 112 are formed from the same or similar material to that of the inner spacers 113. Like the gate spacers 112, the inner spacers 113 can be formed by any suitable techniques such as deposition followed by directional etching.

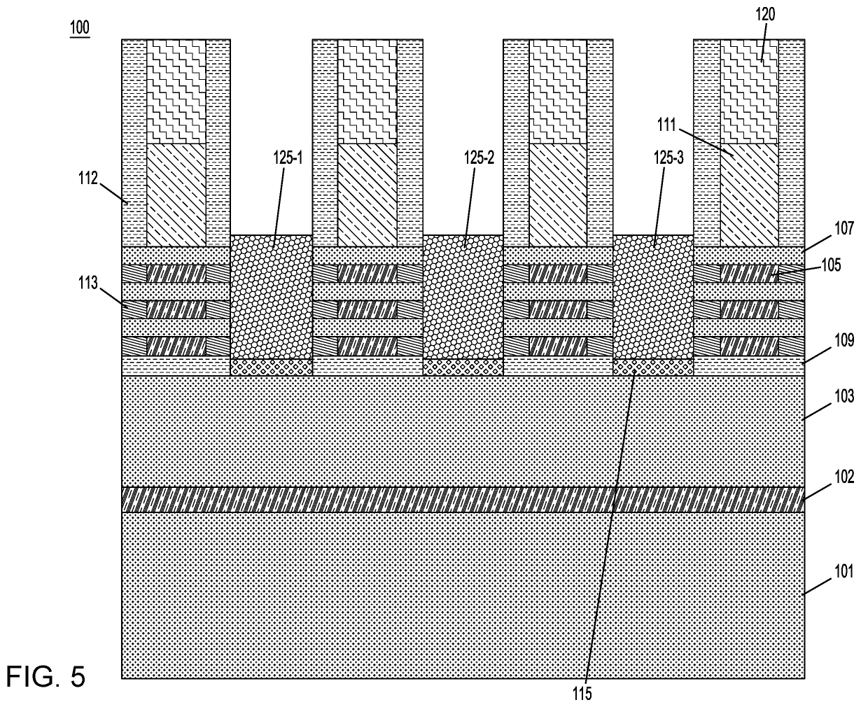

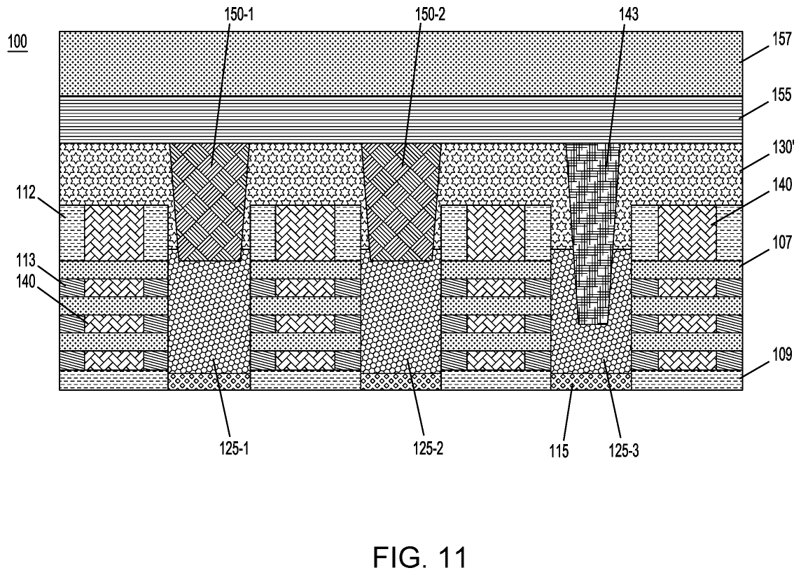

Referring to FIG. 5, etch stop layers 115 (hereinafter “substrate removal etch stop layers 115”) are formed on the exposed portions of the second semiconductor substrate 103 following removal of the exposed portions of the BDI layer 109. As explained in more detail herein in connection with, for example, FIG. 11, the substrate removal etch stop layers 115 are used as etch stop layers during processing to remove the second semiconductor substrate 103. In illustrative embodiments, the substrate removal etch stop layers 115 comprise SiGe or other material so that the second semiconductor substrate 103 can be selectively etched with respect to the substrate removal etch stop layers 115. The substrate removal etch stop layers 115 may be formed in an epitaxial growth process.

Following formation of the substrate removal etch stop layers 115, epitaxial source/drain regions 125-1, 125-2 and 125-3 (collectively “source/drain regions 125”) are grown from the sides of the channel layers 107. In addition, growth of the source/drain regions 125 may also occur from the substrate removal etch stop layers 115 if the substrate removal etch stop layers 115 comprise semiconductor material. As can be seen, the source/drain regions 125 are formed on the substrate removal etch stop layers 115. Side surfaces of respective ones of the channel layers 107 contact a side surface at least one adjacent source/drain region 125. The top surfaces of the source/drain regions 125 are above the top surfaces of uppermost ones of the channel layers 107.

According to a non-limiting embodiment of the present invention, the conditions of the epitaxial growth process for the source/drain regions 125 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the source/drain regions 125 can comprise silicon doped with n-type dopants including, for example, phosphorus (P), arsenic (As) and antimony (Sb). In the case of p-type FETS (pFETs), the source/drain regions 125 can comprise silicon doped with p-type dopants including, for example, boron (B), boron fluoride (BF₂), gallium (Ga), indium (In), and thallium (TI).

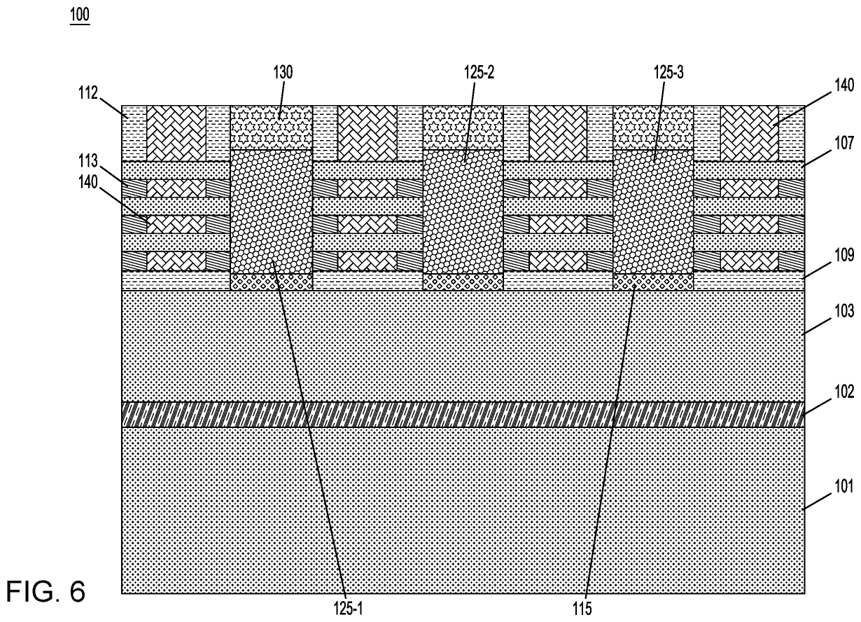

Referring to FIG. 6, an inter-layer dielectric (ILD) layer 130 is deposited to fill in portions on and around the source/drain regions 125. The ILD layer 130 is deposited using deposition techniques such as, for example, CVD, PECVD, RFCVD, PVD, ALD, MBD, PLD, and/or LSMCD, followed by a planarization process, such as, chemical mechanical planarization (CMP) to remove excess portions of the ILD layer 130 deposited on top of the hardmask layers 120 and gate spacers 112, and to remove the hardmask layers 120 and portions of the gate spacers 112 to expose the dummy gate portions 111. The ILD layer 130 may comprise, for example, SiOₓ, SiOC, SiOCN or some other dielectric.

The dummy gate portions 111 are selectively removed to create vacant areas where gate structures will be formed in place of the dummy gate portions 111. The selective removal can be performed using, for example, hot ammonia to remove a-Si. In addition, the sacrificial layers 105 are selectively removed to create vacant areas where gate structures will be formed in place of the sacrificial layers 105. The sacrificial layers 105 are selectively removed with respect to the channel layers 107. The selective removal can be performed using, for example, a dry HCl etch.

Following removal of the dummy gate portions 111 and sacrificial layers 105, the channel layers 107 are suspended, and gate regions 140, including, for example, gate and dielectric portions are formed in the vacant portions left by removal of the dummy gate portions 111, and the sacrificial layers 105. In illustrative embodiments, each gate region 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate regions 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

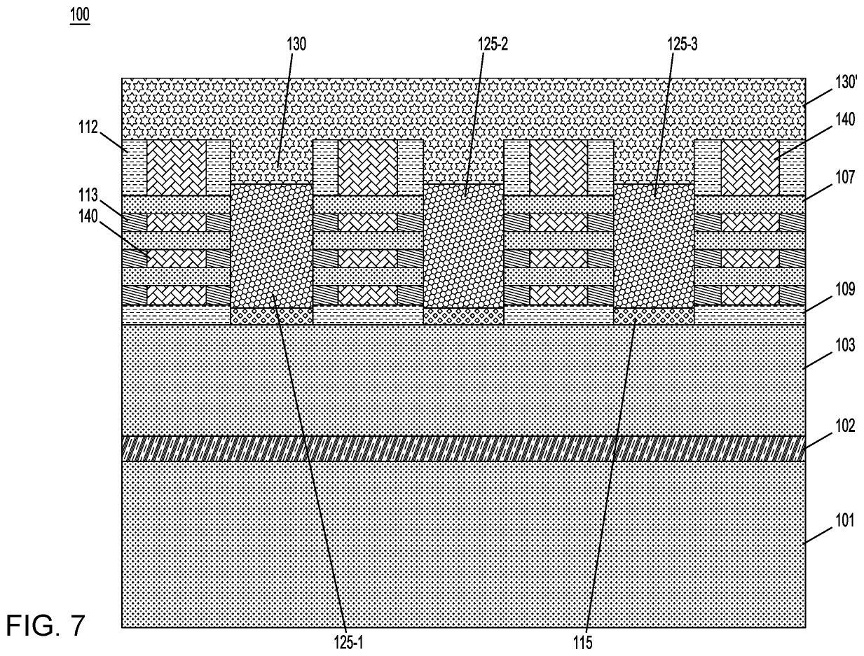

Referring to FIG. 7, additional ILD material is deposited to form an additional ILD layer 130′ on top of the ILD layer 130. The additional ILD layer 130′ is deposited using the same or similar deposition techniques and comprises the same or similar material to that of the ILD layer 130.

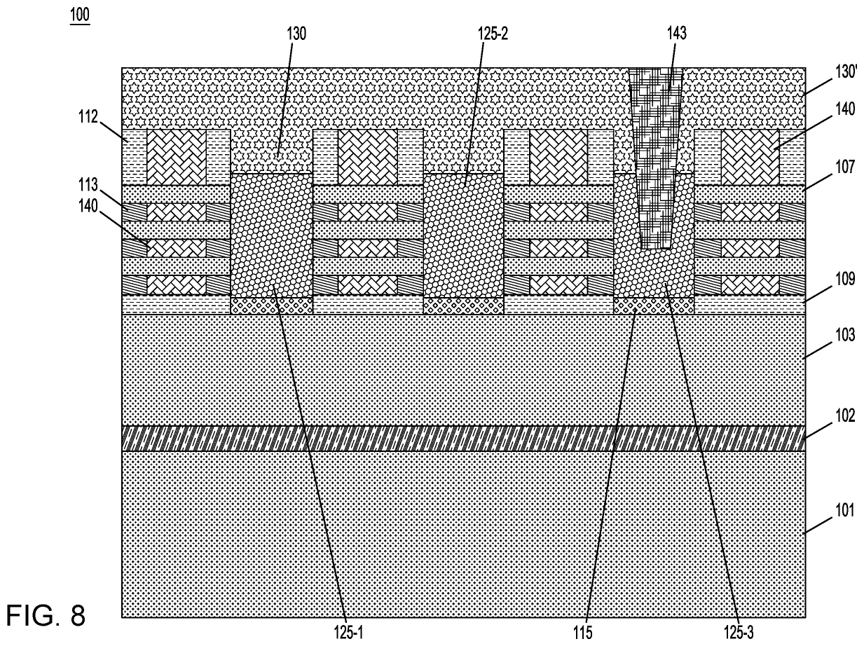

Referring to FIG. 8, parts of ILD layers 130 and 130′ and of source/drain region 125-3 are removed to form a trench through the ILD layers 130 and 130′ and in a portion of the source/drain region 125-3. Dielectric material is deposited into the trench to fill the trench and form a frontside strain inducing region 143. In an illustrative embodiment, the frontside strain inducing region 143 may extend to about midway down into the source/drain region 125-3. The dielectric material of the frontside strain inducing region 143 is deposited using deposition techniques such as, for example, CVD, PECVD, RFCVD, PVD, ALD, MBD, PLD, and/or LSMCD, followed by a planarization process, such as, CMP to remove excess portions of the dielectric material deposited on top of the ILD layer 130′. The dielectric material of the frontside strain inducing region 143 comprises, for example, in the case of an n-type source/drain region for an nFET, a dielectric material with a positive coefficient of thermal expansion (CTE), and, in the case of a p-type source/drain region for a pFET, a dielectric material with a negative CTE. A strain inducing region filled with a dielectric material having a negative CTE induces compressive strain when heated, and a strain inducing region filled with a dielectric material having a positive CTE induces tensile strain when heated. Enhancing tensile strain in the source/drain regions for an nFET increases nFET performance, and enhancing compressive strain in the source/drain regions for a pFET increases pFET performance. With conventional techniques and structures, it is difficult to generate stress in source/drain epitaxial regions. For example, with conventional approaches, when backside source/drain contacts are used, stress in the source/drain regions is difficult to generate since all semiconductor layers under the source/drain regions are removed, thereby reducing performance. Some non-limiting examples of dielectric material having a negative CTE that are used in the illustrative embodiments include, for example, copper (I) oxide (Cu₂O), zirconium tungstate (ZrW₂O₈), beta-quartz, zeolites, etc. Some non-limiting examples of dielectric material having a positive CTE that are used in the illustrative embodiments include, for example, silicon nitride (SiN), silicon oxide (SiO₂), SiNCH, organosilicate glass (SiCOH).

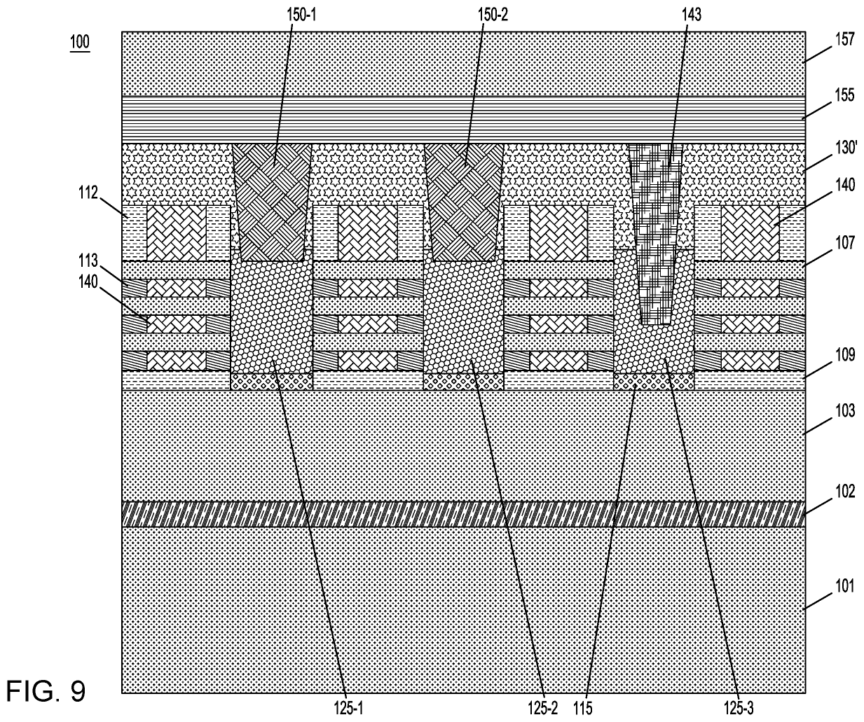

Referring to FIG. 9, frontside source/drain contacts 150-1 and 150-2 (collectively “frontside source/drain contacts 150) to source/drain regions 125-1 and 125-2 are formed in the ILD layers 130 and 130′. In forming the frontside source/drain contacts 150, openings are formed through portions of the ILD layers 130 and 130′. The openings expose portions the source/drain regions 125 on which the frontside source/drain contacts 150 are to be formed. According to an embodiment, masks are formed on parts of the ILD layer 130′, and exposed portions of the ILD layers 130 and 130′ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the openings to form the frontside source/drain contacts 150. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the ILD layer 130′.

The frontside source/drain contacts 150-1 and 150-2 contact respective ones of the source/drain regions 125-1 and 125-2. The frontside source/drain contacts 150 extend through the ILD layers 130 and 130′ to land on and contact the corresponding source/drain regions 125.

Frontside BEOL interconnects 155 are formed on the ILD layer 130′ including the frontside source/drain contacts 150. As can be seen, the frontside source/drain contacts 150 contact the frontside BEOL interconnects 155. A carrier wafer 157 is bonded to the frontside BEOL interconnects 155. The frontside BEOL interconnects 155 include various BEOL interconnect structures which may electrically connect to the frontside source/drain contacts 150 and the frontside gate contacts (not shown). The carrier wafer 157 may be formed of materials similar to that of the first semiconductor substrate 101, and may be formed over the frontside BEOL interconnects 155 using a wafer bonding process, such as dielectric-to-dielectric bonding.

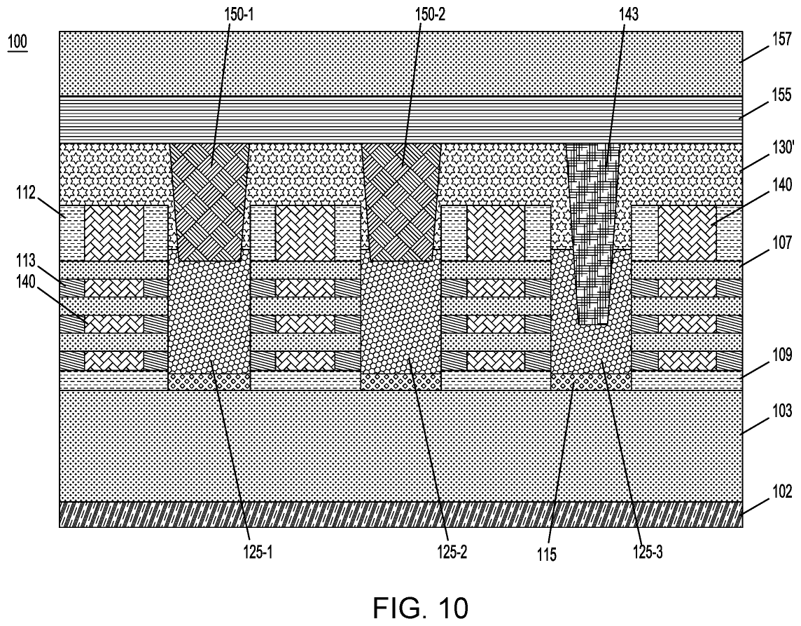

Referring to FIG. 10, using the carrier wafer 157, the semiconductor structure 100 may be “flipped” (e.g., rotated 180 degrees) so that the structure is inverted. In addition, the first semiconductor substrate 101 is removed from the backside of the semiconductor structure 100. The removal process, which comprises etching of the first semiconductor substrate 101, stops at the etch stop layer 102. For example, the first semiconductor substrate 101 is selectively etched with an etchant that selectively etches silicon with respect to a material of the etch stop layer 102 (e.g., SiGe).

Referring to FIG. 11, the etch stop layer 102 and the second semiconductor substrate 103 (e.g., silicon layer) are removed from the semiconductor structure 100 to the substrate removal etch stop layers 115 and the remaining portions of the BDI layer 109. The etch stop layer 102 is removed, followed by removal of the second semiconductor substrate 103. The remaining portions of the BDI layer 109 and the substrate removal etch stop layers 115 are exposed. Etching processes for removal of the etch stop layer 102 include, for example, IBE by Ar/CHF3 based chemistry.

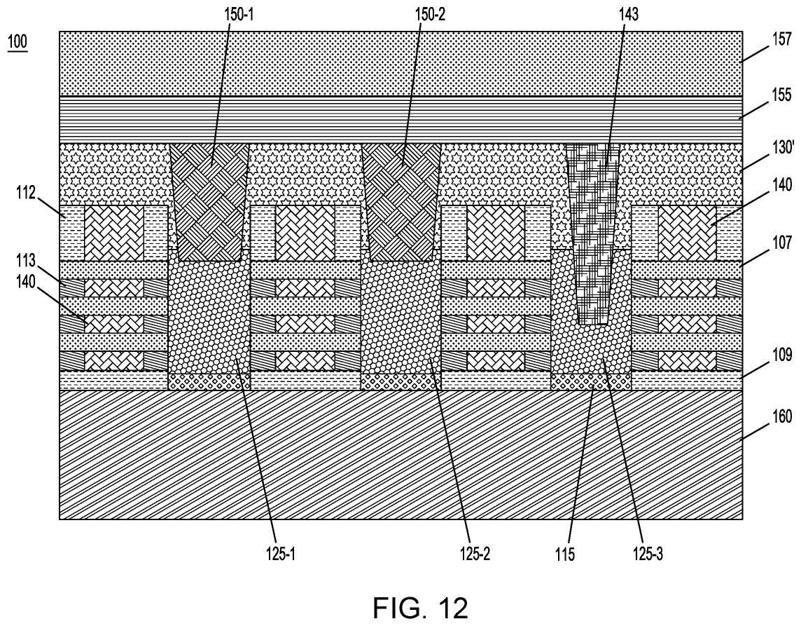

Referring to FIG. 12, a backside ILD layer 160 is deposited to fill in areas formerly occupied by the etch stop layer 102 and the second semiconductor substrate 103. The backside ILD layer 160 is deposited using deposition techniques such as, for example, CVD, PECVD, RFCVD, PVD, ALD, MBD, PLD, and/or LSMCD, followed by a planarization process, such as, CMP. The backside ILD layer 160 may comprise, for example, SiOₓ, SiOC, SiOCN or some other dielectric.

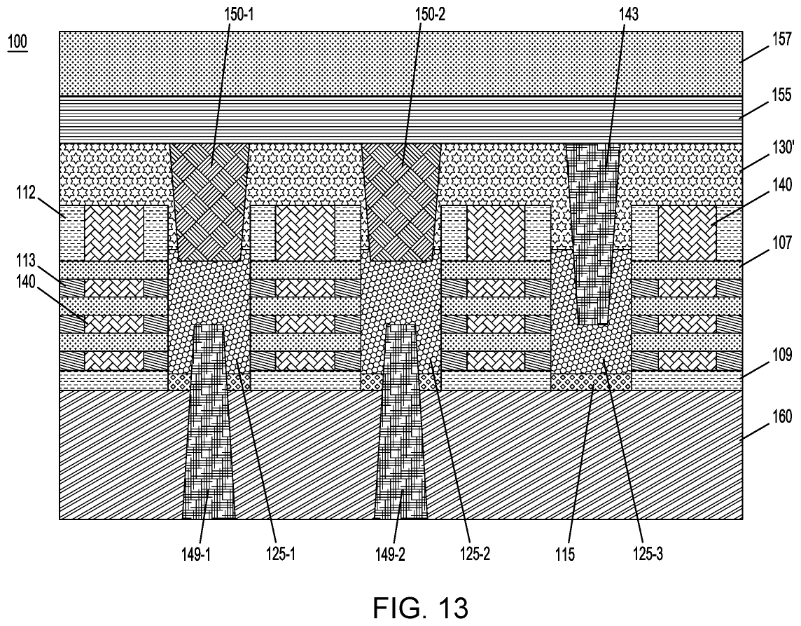

Referring to FIG. 13, parts of backside ILD layer 160, the substrate removal etch stop layers 115 and source/drain regions 125-1 and 125-2 are removed to form trenches through the backside ILD layer 160, the substrate removal etch stop layers 115 and in portions of the source/drain regions 125-1 and 125-2. Dielectric material is deposited into the trench to fill the trench and form backside strain inducing regions 149-1 and 149-2. In an illustrative embodiment, the backside strain inducing regions 149-1 and 149-2 may extend to about midway up into the source/drain regions 125-1 and 125-2. The dielectric material of the backside strain inducing regions 149-1 and 149-2 is deposited using deposition techniques such as, for example, CVD, PECVD, RFCVD, PVD, ALD, MBD, PLD, and/or LSMCD, followed by a planarization process, such as, CMP to remove excess portions of the dielectric material deposited on the backside ILD layer 160. Like the frontside strain inducing region 143, the dielectric material of the backside strain inducing regions 149-1 and 149-2 comprises, for example, in the case of an n-type source/drain region for an nFET, a dielectric material with a positive CTE, and, in the case of a p-type source/drain region for a pFET, a dielectric material with a negative CTE.

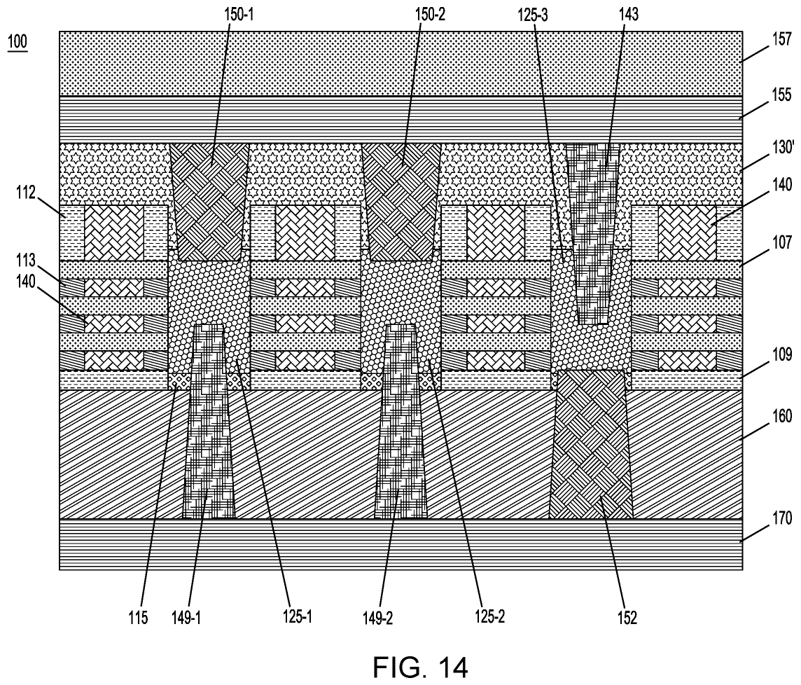

Referring to FIG. 14, an opening is formed in a portion of the backside ILD layer 160 to expose part of the source/drain region 125-3 on which backside source/drain contact 152 is to be formed. According to an embodiment, masks are formed on parts of the backside ILD layer 160, and an exposed portion of the backside ILD layer 160 corresponding to where the backside source/drain contact 152 is to be formed is removed using, for example, a dry etching process using a RIE or IBE process, a wet chemical etch process or a combination of these etching processes. A dry etch may be performed using a plasma. Such wet or dry etch processes include, for example, IBE by Ar/CHF3 based chemistry.

The backside source/drain contact 152 is formed in the backside ILD layer 160 in the opening. Metal layers are deposited in the opening to form the backside source/drain contact 152. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 160.

The backside source/drain contact 152 contacts a backside of the source/drain region 125-3. The backside source/drain contact 152 extends through a portion of the backside ILD layer 160 and through one of the substrate removal etch stop layers 115 and the adjacent BDI layer 109 to land on and contact the backside (bottom surface in FIG. 14) of the corresponding source/drain region 125-3.

Backside power delivery network (BSPDN) layers 170 (also referred to herein as backside interconnects) are formed on the backside ILD layer 160, the backside strain inducing regions 149-1 and 149-2 and on the backside source/drain contact 152. The BSPDN layers 170 include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits. The backside source/drain contact 152 is connected to the BSPDN.

Although the embodiment depicts backside strain inducing regions 149-1 and 149-2 in source/drain regions 125-1 and 125-2, and a frontside strain inducing region 143 in source/drain region 125-3, the embodiments are not necessarily limited thereto, and other arrangements of strain inducing regions may be used depending on design constraints. For example, a given source/drain region may comprise a frontside or backside strain inducing region instead of a backside or frontside strain inducing region and corresponding oppositely positioned source/drain contact depending on design.

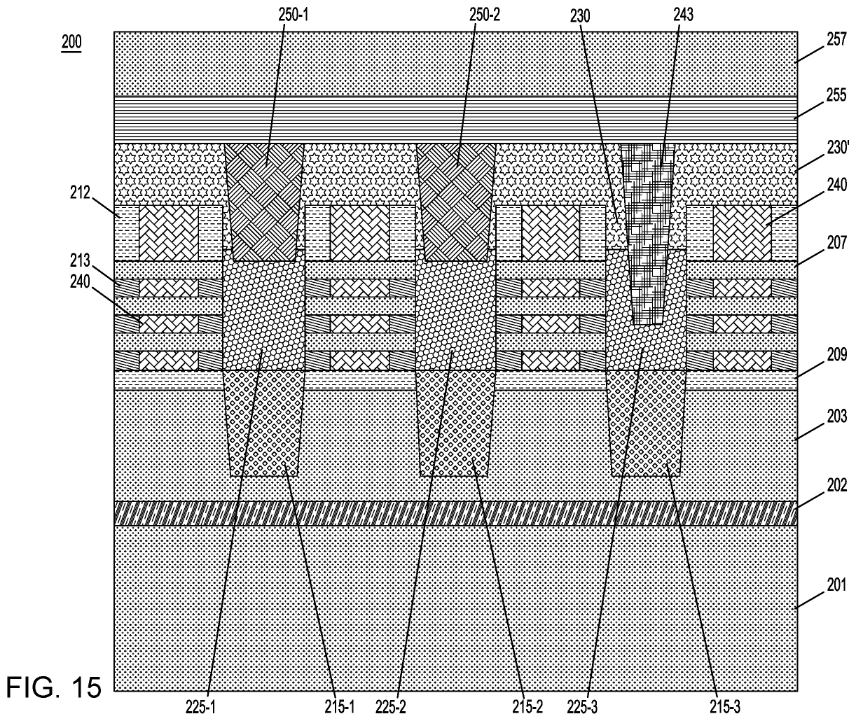

Referring to FIGS. 15-24, certain elements of the semiconductor structure 200 in FIGS. 15-24 are the same or similar to the elements of semiconductor structure 100 in FIGS. 1-14, and have similar reference numbers. For example, referring to FIG. 15, the first semiconductor substrate 201, etch stop layer 202, second semiconductor substrate 203, channel layers 207, BDI layers 209, gate spacers 212, inner spacers 213, source/drain regions 225-1, 225-2 and 225-3 (collectively “source/drain regions 225”), ILD layers 230′ and 230, gate structures 240, frontside strain inducing region 243, frontside source/drain contacts 250-1 and 250-2 (collectively “frontside source/drain contacts 250”), BEOL interconnects 255 and carrier wafer 257 of the semiconductor structure 200 are the same as or similar to the first semiconductor substrate 101, etch stop layer 102, second semiconductor substrate 103, channel layers 107, BDI layers 109, gate spacers 112, inner spacers 113, source/drain regions 125-1, 125-2 and 125-3, ILD layers 130′ and 130, gate regions 140, frontside strain inducing region 143, frontside source/drain contacts 150-1 and 150-2, frontside BEOL interconnects 155 and carrier wafer 157 of the semiconductor structure 100. Unlike the semiconductor structure 100, the semiconductor structure 200 includes sacrificial placeholder layers 215-1, 215-2 and 215-3 (collectively “sacrificial placeholder layers 215”) instead of the substrate removal etch stop layers 115. The sacrificial placeholder layers 215 comprise, for example, SiGe.

Like the processing for the semiconductor structure 100 in FIG. 9, FIG. 15 depicts a semiconductor structure 200 following formation of a frontside strain inducing region 243 in an epitaxial source/drain region 225-3, formation of frontside source/drain contacts 250, formation of frontside BEOL interconnects 255 and a carrier wafer 257 formed over the frontside BEOL interconnects 255 using a wafer bonding process, such as dielectric-to-dielectric bonding. For the sake of brevity, duplicative processing descriptions have been omitted.

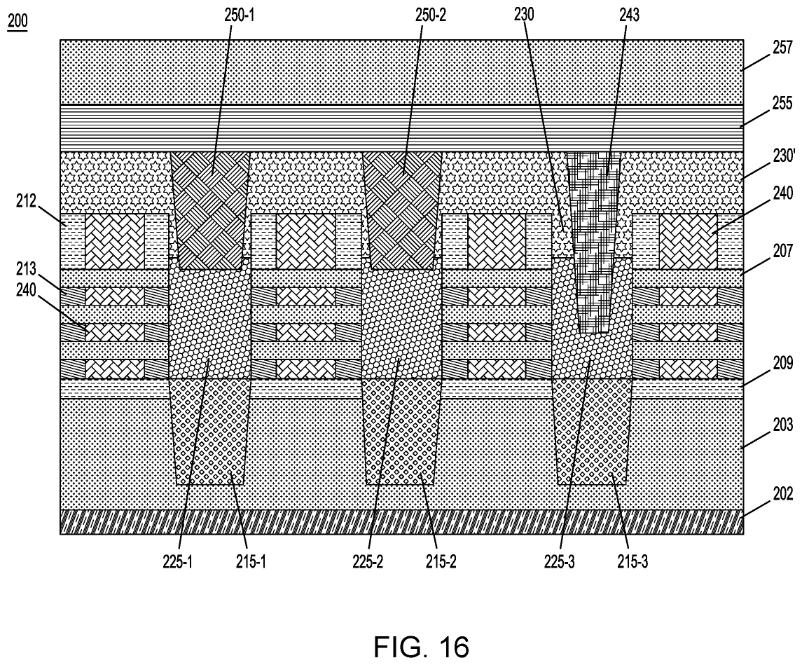

Like the processing for the semiconductor structure 100 in FIG. 10, referring to FIG. 16, using the carrier wafer 257, the semiconductor structure 200 may be flipped so that the structure is inverted. In addition, the first semiconductor substrate 201 is removed from the backside of the semiconductor structure 200, stopping at the etch stop layer 202.

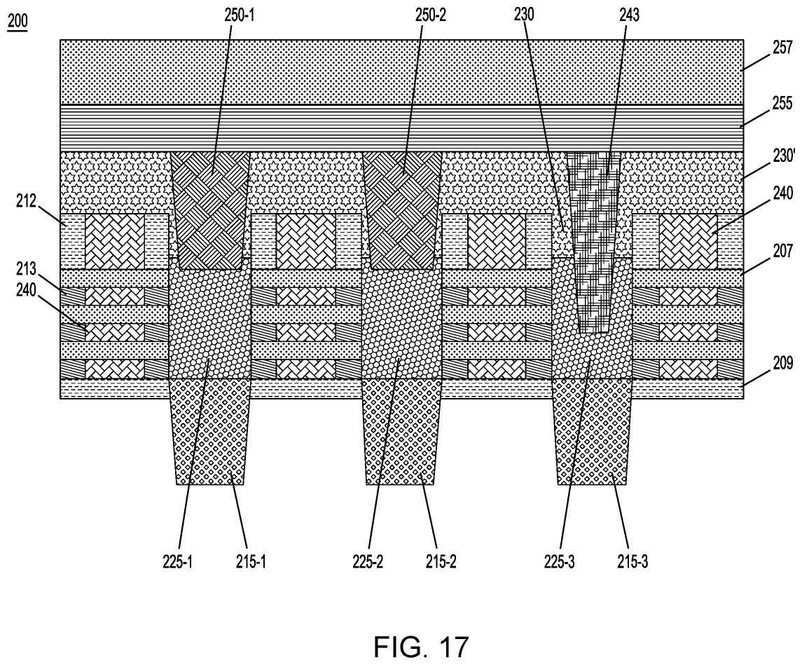

Similar to the processing for the semiconductor structure 100 in FIG. 11, referring to FIG. 17, the etch stop layer 202 and the second semiconductor substrate 203 (e.g., silicon layer) are selectively removed from the semiconductor structure 200 with respect to the sacrificial placeholder layers 215 and the remaining portions of the BDI layer 209. The etch stop layer 202 is removed, followed by removal of the second semiconductor substrate 203. The remaining portions of the BDI layer 209 and the sacrificial placeholder layers 215 are exposed. Etching processes for removal of the etch stop layer 202 include, for example, IBE by Ar/CHF3 based chemistry.

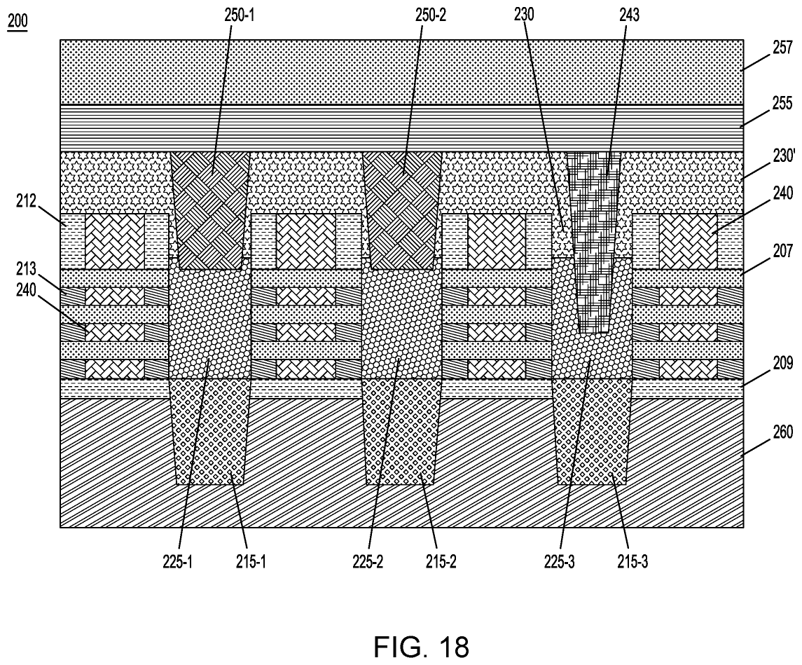

Similar to the processing for the semiconductor structure 100 in FIG. 12, referring to FIG. 18, a backside ILD layer 260 is deposited to fill in areas formerly occupied by the etch stop layer 202 and the second semiconductor substrate 203. The backside ILD layer 260 is deposited on and around the sacrificial placeholder layers 215 and on the remaining portions of the BDI layer 209 using deposition techniques such as, for example, CVD, PECVD, RFCVD, PVD, ALD, MBD, PLD, and/or LSMCD, followed by a planarization process, such as, CMP. The backside ILD layer 260 may comprise, for example, SiOₓ, SiOC, SiOCN or some other dielectric.

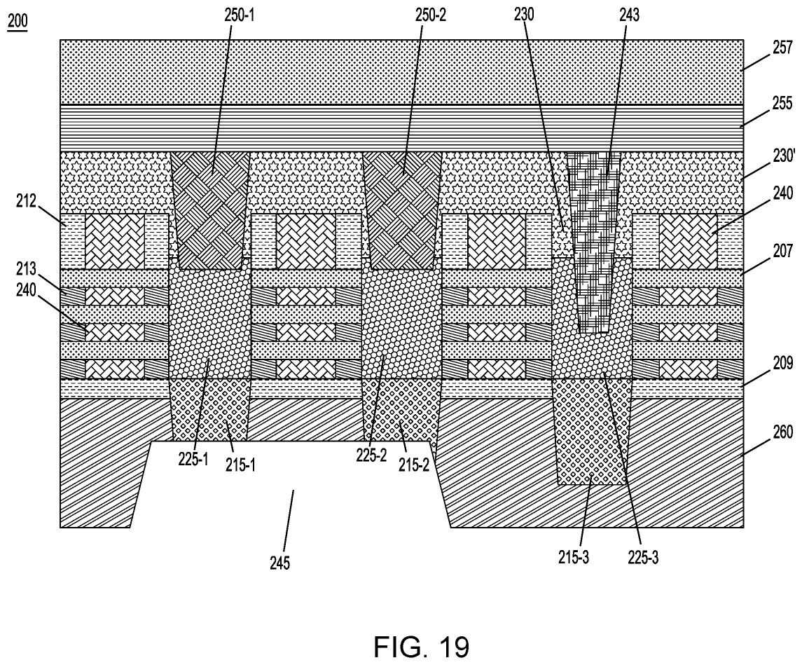

Referring to FIG. 19, part of the backside ILD layer 260 is removed to expose the sacrificial placeholder layers 215-1 and 215-2, and part of the sacrificial placeholder layers 215-1 and 215-2 are removed, forming opening 245, which may also be referred to as a trench. The part of the backside ILD layer 260 is etched using, for example, a RIE process, and the parts of the sacrificial placeholder layers 215-1 and 215-2 are etched using, for example, a selective dry or wet etch process.

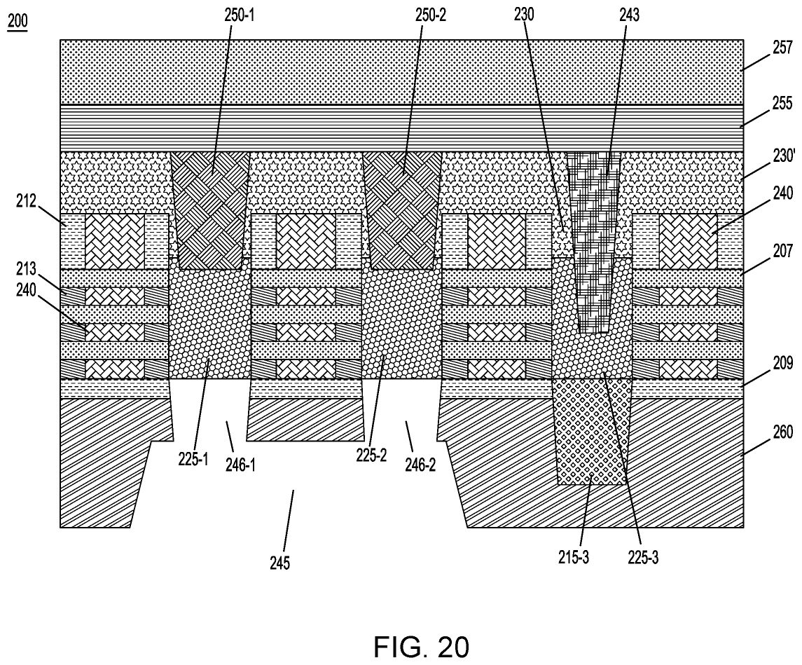

Referring to FIG. 20, the exposed sacrificial placeholder layers 215-1 and 215-2 are selectively removed to form additional openings 246-1 and 246-2 (or trenches) exposing the bottom surfaces of the source/drain regions 225-1 and 225-2. The sacrificial placeholder layers 225-1 and 225-2 are removed using, for example, a selective dry or wet etch process.

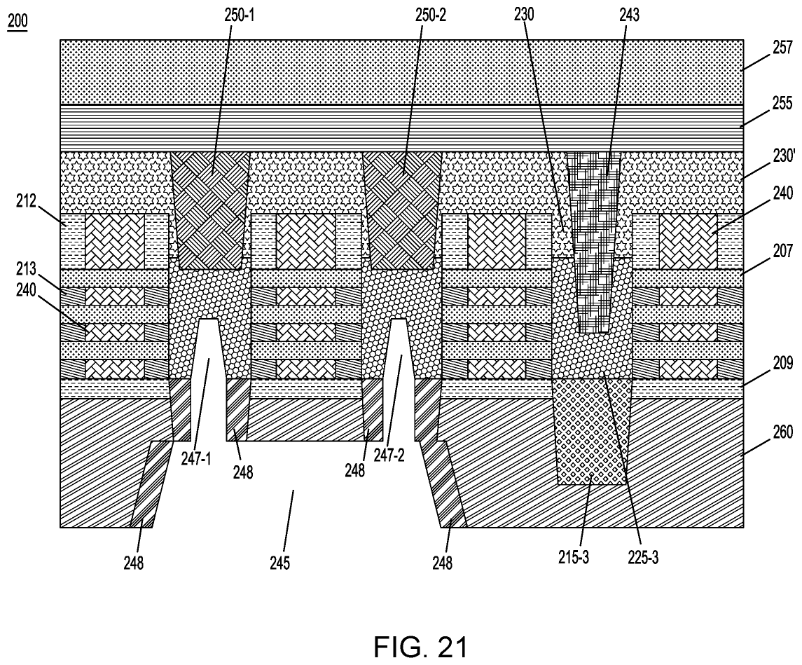

Referring to FIG. 21, spacers 248 are formed on sides of the opening 245 and the additional openings 246-1 and 246-2. The spacers 248 can be formed by any suitable techniques such as deposition followed by directional etching. Deposition may include but is not limited to, ALD or CVD. Directional etching may include, but is not limited to, RIE. The spacer material can comprise for example, one or more dielectrics, including, but not necessarily limited to, SiN, SiON, SiOC, SiCN, BN, SiBN, SiBCN, SiOCN, SiOₓ, and combinations thereof.

Following formation of the spacers 248, exposed portions of the source/drain regions 225-1 and 225-2 are removed to form trenches 247-1 and 247-2 in the source/drain regions 225-1 and 225-2. As can be seen, the spacers 248 act as masks during etching of the source/drain regions 225-1 and 225-2 to reduce the critical dimensions of the trenches 247-1 and 247-2 compared to if no spacers 248 were added.

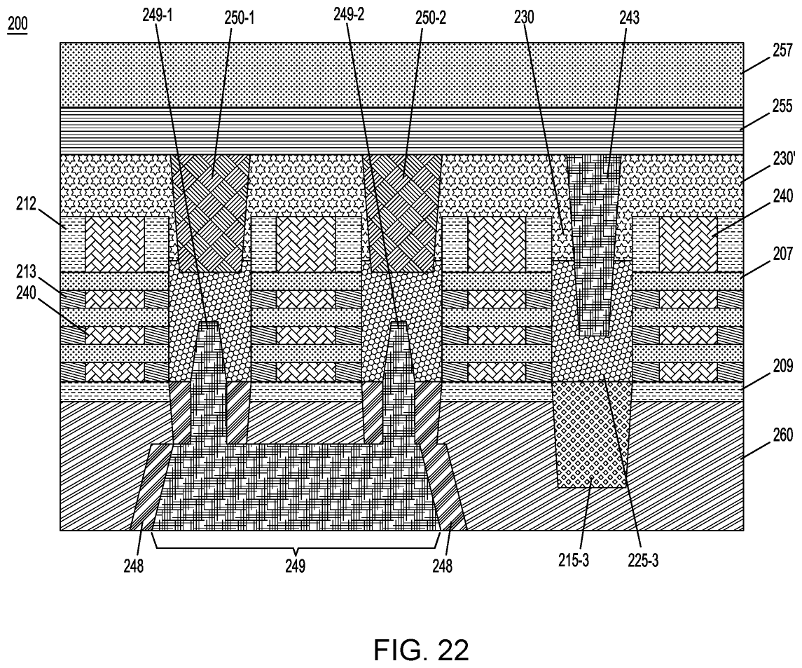

Referring to FIG. 22, dielectric material is deposited to fill the openings 245, 246-1, 246-2, 247-1 and 247-2 (e.g., trenches) and form backside strain inducing region 249 including portions 249-1 and 249-2 corresponding to source/drain regions 225-1 and 225-2. As can be seen, the backside strain inducing region 249 extends from a backside of the semiconductor structure 200 through the backside ILD layer 260 into the source/drain regions 225-1 and 225-2. In the direction from the backside to the frontside of the semiconductor structure 200 (upward direction in FIG. 22), a width of the backside strain inducing region 249 (left to right direction in FIG. 22) and an area of the backside strain inducing region 249 decreases.

The parts of the source/drain regions 225-1 and 225-2 are etched using, for example, a RIE process. In an illustrative embodiment, the portions 249-1 and 249-2 of the backside strain inducing region 249 may extend to about midway up into the source/drain regions 225-1 and 225-2. The dielectric material of the backside strain inducing region 249 including portions 249-1 and 249-2 is deposited using deposition techniques such as, for example, CVD, PECVD, RFCVD, PVD, ALD, MBD, PLD, and/or LSMCD, followed by a planarization process, such as, CMP to remove excess portions of the dielectric material deposited on the backside ILD layer 260. Like the frontside strain inducing regions 143 and 243 and backside strain regions 149-1 and 149-2, the dielectric material of the backside strain inducing region 249 including portions 249-1 and 249-2 comprises, for example, in the case of an n-type source/drain region for an nFET, a dielectric material with a positive CTE, and, in the case of a p-type source/drain region for a pFET, a dielectric material with a negative CTE.

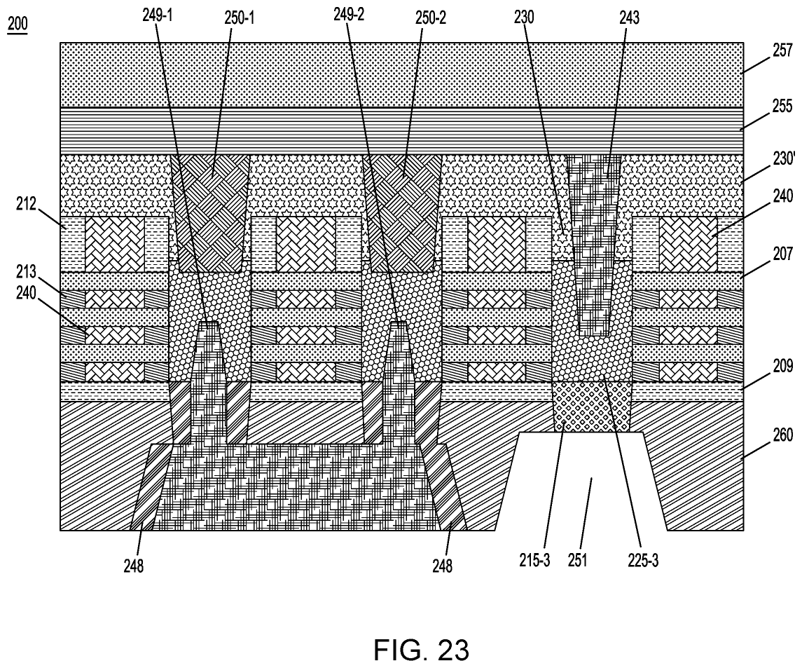

Referring to FIG. 23, part of the backside ILD layer 260 is removed to expose the sacrificial placeholder layer 215-3, and part of the sacrificial placeholder layer 215-3 is removed, forming opening 251, which may also be referred to as a trench. The part of the backside ILD layer 260 is etched using, for example, a RIE process, and the part of the sacrificial placeholder layers 215-3 is etched using, for example, a selective dry etch process.

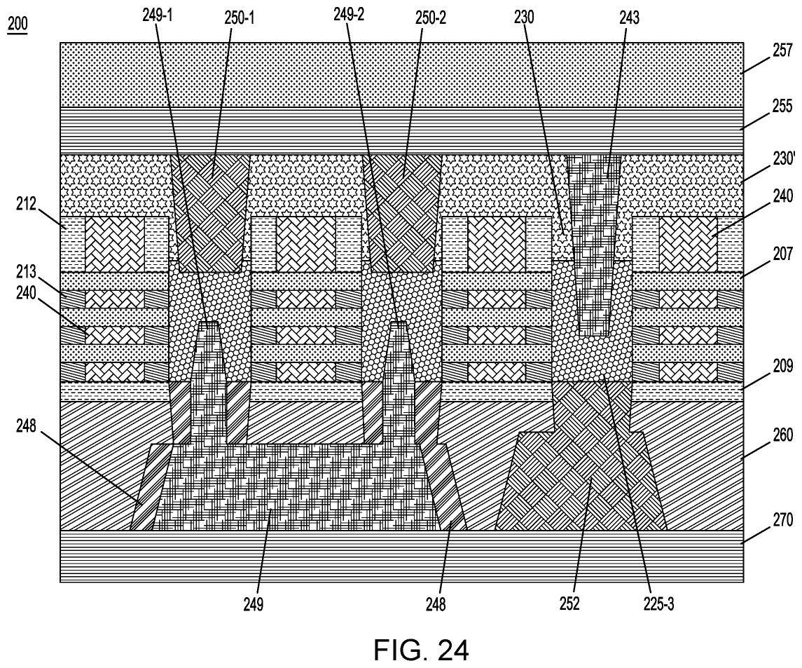

Referring to FIG. 24, a remaining part of the sacrificial placeholder layer 215-3 is removed using, for example, a selective dry or wet etch process to expose the backside surface of the source/drain region 225-3 on which backside source/drain contact 252 is to be formed. According to an embodiment, masks are formed on parts of the backside ILD layer 260, and an exposed portion of the backside ILD layer 260 corresponding to where the backside source/drain contact 252 is to be formed is removed using, for example, a dry etching process using a RIE or IBE process, a wet chemical etch process or a combination of these etching processes. A dry etch may be performed using a plasma. Such wet or dry etch processes include, for example, IBE by Ar/CHF3 based chemistry.

The backside source/drain contact 252 is formed in and through the backside ILD layer 260 and in and through the BDI layer 209 to contact a backside (bottom surface in FIG. 24) of the source/drain region 225-3. Metal layers are deposited in the opening to form the backside source/drain contact 252. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 260.

The backside source/drain contact 252 contacts a backside of the source/drain region 225-3. The backside source/drain contact 252 extends through a portion of the backside ILD layer 260 and the BDI layer 209 to land on and contact the backside of the corresponding source/drain region 225-3.

Backside power delivery network (BSPDN) layers 270 (also referred to herein as backside interconnects) are formed on the backside ILD layer 260, spacers 248, the backside strain inducing region 249 and on the backside source/drain contact 252. The BSPDN layers 270 include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits. The backside source/drain contact 252 is connected to the BSPDN.

Although the embodiment depicts backside strain inducing region 249 with portions 249-1 and 249-2 in source/drain regions 225-1 and 225-2, and a frontside strain inducing region 243 in source/drain region 225-3, the embodiments are not necessarily limited thereto, and other arrangements of strain inducing regions may be used depending on design constraints. For example, a given source/drain region may comprise a frontside or backside strain inducing region instead of a backside or frontside strain inducing region and corresponding oppositely positioned source/drain contact depending on design.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming dielectric filled strain inducing trenches in source/drain regions. With conventional approaches, when source/drain contacts are formed, stress in the source/drain regions is difficult to generate since semiconductor layers on the source/drain regions are removed to form the contacts. This lack of stress reduces device performance. A strain inducing region filled with a dielectric material having a negative or positive CTE induces compressive or tensile strain when heated. Enhancing tensile strain in the source/drain regions for an nFET increases nFET performance, and enhancing compressive strain in the source/drain regions for a pFET increases pFET performance. Accordingly, the embodiments provide solutions which form dielectric trenches to induce tensile strain in nFET source/drain regions and compressive strain in pFET source/drain regions.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
at least one epitaxial source/drain region; and
a dielectric layer disposed in a trench in the at least one epitaxial source/drain region.

2. The semiconductor device of claim 1, wherein the dielectric layer comprises one of a material with a negative coefficient of thermal expansion and a material with a positive coefficient of thermal expansion.

3. The semiconductor device of claim 1, wherein the at least one epitaxial source/drain region corresponds to a p-type transistor and the dielectric layer comprises a material with a negative coefficient of thermal expansion.

4. The semiconductor device of claim 1, wherein the at least one epitaxial source/drain region corresponds to an n-type transistor and the dielectric layer comprises a material with a positive coefficient of thermal expansion.

5. The semiconductor device of claim 1, wherein the dielectric layer is disposed on a first side of the at least one epitaxial source/drain region.

6. The semiconductor device of claim 5, further comprising a source/drain contact disposed on a second side of the at least one epitaxial source/drain region, wherein the second side is opposite the first side.

7. The semiconductor device of claim 5, wherein the first side corresponds to one of a frontside and a backside of the semiconductor device.

8. The semiconductor device of claim 1, wherein a first portion of the trench is disposed in the at least one epitaxial source/drain region and a second portion of the trench is disposed in an additional dielectric layer on the at least one epitaxial source/drain region.

9. The semiconductor device of claim 8, wherein a first portion of the dielectric layer is disposed in the first portion of the trench and a second portion of the dielectric layer is disposed in the second portion of the trench.

10. The semiconductor device of claim 9, further comprising a spacer layer disposed adjacent the second portion of the dielectric layer.

11. The semiconductor device of claim 1, further comprising a stacked structure comprising a plurality of gate structures alternately stacked with a plurality of channel layers, wherein the at least one epitaxial source/drain region is disposed on a side of the stacked structure.

12. The semiconductor device of claim 1, wherein part of the dielectric layer is disposed through a semiconductor layer, the semiconductor layer contacting a surface of the at least one epitaxial source/drain region.

13. A semiconductor device comprising:
a first nanosheet structure comprising a first plurality of gate structures alternately stacked with a first plurality of channel layers;
a second nanosheet structure comprising a second plurality of gate structures alternately stacked with a second plurality of channel layers; and
at least one epitaxial source/drain region disposed between the first and second nanosheet structures; and
a dielectric layer disposed in a trench in the at least one epitaxial source/drain region.

14. The semiconductor device of claim 13, wherein the dielectric layer comprises one of a material with a negative coefficient of thermal expansion and a material with a positive coefficient of thermal expansion.

15. The semiconductor device of claim 13, wherein the dielectric layer is disposed on a first side of the at least one epitaxial source/drain region.

16. The semiconductor device of claim 15, further comprising a source/drain contact disposed on a second side of the at least one epitaxial source/drain region, wherein the second side is opposite the first side.

17. The semiconductor device of claim 16, wherein the source/drain contact is connected to a backside power delivery network.

18. A semiconductor device comprising:
a first epitaxial source/drain region corresponding to a first transistor;
a second epitaxial source/drain region corresponding to a second transistor;
a first dielectric layer disposed in a first trench in the first epitaxial source/drain region; and
a second dielectric layer disposed in a second trench in the second epitaxial source/drain region;
wherein the first trench is disposed on a first side of the semiconductor device and the second trench is disposed on a second side of the semiconductor device opposite the first side.

19. The semiconductor device of claim 18, wherein the first dielectric layer and second dielectric layer each comprise one of a material with a negative coefficient of thermal expansion and a material with a positive coefficient of thermal expansion.

20. The semiconductor device of claim 18, further comprising:
a first source/drain contact disposed on the first epitaxial source/drain region on the second side of the semiconductor device; and
a second source/drain contact disposed on the second epitaxial source/drain region on the first side of the semiconductor device.
